(19) United States
(12) Patent Application Publication
(10) Pub. No.: US 2023/0202842 A1
(43) Pub. Date: Jun. 29, 2023

(54) METAL OXIDE PARTICLES, LAMINATED BODY, SOLAR CELL, PHOTOCONDUCTOR, METHOD OF MANUFACTURING METAL OXIDE PARTICLES, AND METHOD OF MANUFACTURING LAMINATED BODY

(71) Applicant: Hidetoshi KAMI, Chiba (JP)

(72) Inventor: Hidetoshi KAMI, Chiba (JP)

(21) Appl. No.: 18/075,435

(22) Filed: Dec. 6, 2022

(30) Foreign Application Priority Data
Dec. 24, 2021 (JP) 2021-211039

(51) Int. Cl. C01B 13/08; C01B 13/02; H01L 31/0224

(52) U.S. Cl. CPC C01B 13/08; C01B 13/0222; H01L 31/022425; G03G 2215/2048

(57) ABSTRACT

Metal oxide particles having: (1) a volume ratio (a) in 0.7 μm band of 5 to 40 vol %, (2) a volume ratio (b) in 13 μm band of 20 to 45 vol %, (3) a volume ratio (c) in 1.3 μm band of 20 to 50 vol %, and (4) a sum of the volume ratios (a), (b), and (c) of 60 to 100 vol %. The 0.7 μm, 13 μm, and 1.3 μm bands are particle size distributions having peaks at 0.3 to 1.2 μm, 0.3 to 20 μm, and 0.7 to 3 μm, respectively. The volume ratios (a), (b), and (c) of each band have peaks near 0.7 μm, 1.3 μm, and 13 μm in a particle size distribution curve, and being obtained by calculating an abundance ratio of particles in each band from a numerical integration of distribution curves obtained by further dividing the particle size distribution curve into three bands.

### CROSS-REFERENCE TO RELATED APPLICATIONS

This patent application is based on and claims priority pursuant to 35 U.S.C. § 119(a) to Japanese Patent Application No. 2021-211039, filed on Dec. 24, 2021, in the Japan Patent Office, the entire disclosure of which is hereby incorporated by reference herein.

### BACKGROUND

### Technical Field

The present disclosure relates to metal oxide particles, a laminated body, a solar cell, a photoconductor, a method of manufacturing metal oxide particles, and a method of manufacturing a laminated body.

### Related Art

An aerosol deposition method (“AD method”) is known as a method for forming a ceramic coating film (ceramic layer) on a substrate surface at room temperature. In the AD method, it is common to use metal materials such as stainless steel and iron or glass as the substrate to be subjected to ceramic coating. However, in recent years, a technique has been developed in which a resin material is used as a substrate and a ceramic coating film is formed on the resin material.

If a ceramic coating is applied to a resin material, sufficient adhesion of the ceramic material to the substrate is desired. In addition, ceramic coating films desirably have toughness that is adequate for the performance of bulk ceramics. When applying the ceramic coating technique for such a resin material to industrial products, the issue of improving the adhesiveness and the toughness of the ceramic coating film remains.

### SUMMARY

Embodiments of the present invention provides metal oxide particles satisfying conditions (1) to (4) described below:

(1) a volume ratio (a) in a 0.7 μm band of 5 vol % or more and 40 vol % or less,

(2) a volume ratio (b) in a 13 μm band of 20 vol % or more and 45 vol % or less,

(3) a volume ratio (c) in a 1.3 μm band of 20 vol % or more and 50 vol % or less, and

(4) a sum of the volume ratio (a), the volume ratio (b), and the volume ratio (c) of from 60 vol % or more and 100 vol % or less,

where:

the 0.7 μm band is defined as a particle size distribution having a peak at 0.3 μm or more and less than 1.2 μm,

13 μm hand is defined as a particle size distribution having a peak at 0.3 μm or more and less than 20 μm, and

1,3 μm band is defined as a particle size distribution having a peak at 0.7 μm or more and less than 3μm,

the volume ratio (a), the volume ratio (b), and the volume ratio (c) of each band. having peaks near 0.7 μm, 1.3 μm, and 13 μm in a particle size distribution curve, and are obtained by calculating an abundance ratio of particles in each band from a numerical integration of distribution curves obtained by further dividing the particle size distribution curve into three bands.

### BRIEF DESCRIPTION OF THE DRAWINGS

A more complete appreciation of embodiments of the present disclosure and many of the attendant advantages and features thereof can be readily obtained and understood from the following detailed description with reference to the accompanying drawings, wherein:

FIG. 1 is an example representing a particle size distribution of metal oxide particles and specific bands of particle size;

FIG. 2 is a schematic diagram for explaining a mechanism of ceramic coating in an AD method;

FIG. 3 is an example of another particle size distribution of metal oxide particles;

FIG. 4 is an example of still another particle size distribution of metal oxide particles;

FIG. 5 is an example of still another particle size distribution of metal oxide particles;

FIG. 6 is an example of still another particle size distribution of metal oxide particles;

FIG. 7 is an example of still another particle size distribution of metal oxide particles;

FIG. 8 is a diagram illustrating a layer structure of an example photoconductor;

FIG. 9 is a diagram illustrating a layer structure of an example photoconductor;

FIG. 10 is a diagram illustrating a layer structure of an example photoconductor;

FIG. 11 is a diagram illustrating a layer structure of an example photoconductor;

FIG. 12 is a diagram illustrating a layer structure of an example photoconductor;

FIG. 13 is a diagram illustrating a layer structure of an example photoconductor;

FIG. 14 is an explanatory diagram illustrating a perovskite solar cell as an example of a laminated body according to an embodiment of the present disclosure; and

FIG. 15 is a diagram illustrating a layer structure of the laminated body according to the embodiment of the present disclosure.

The accompanying drawings are intended to depict embodiments of the present disclosure and should not be interpreted to limit the scope thereof. The accompanying drawings are not to be considered as drawn to scale unless explicitly noted. Also, identical or similar reference numerals designate identical or similar components throughout the several views.

### DETAILED DESCRIPTION

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. As used herein, the singular forms “a,” “an,” and “the” are intended to include the plural forms as well, unless the context clearly indicates otherwise.

According to the present disclosure, it is possible to provide metal oxide particles that can easily form a tough metal oxide layer on a substrate layer containing an organic material.

The toughening of a metal oxide layer produced by an AD method varies depending on a powder material used for film formation, a substrate, and film formation conditions, and thus, the conditions may not be uniformly determined. To obtain toughness, it is desirable to find optimum film formation conditions for each material. When selecting an organic material as the substrate, the choice for such conditions narrows down further, which makes it more difficult to find the optimum conditions. Therefore, it is desirable to develop a technique for expanding the range of optimum conditions under which the AD method may be utilized with respect to the powder material, the substrate, and film formation conditions.

The present disclosure solves the above-described problems.

Embodiments of the present disclosure are described in detail below

(Metal Oxide Particles)

Metal oxide particles of the present disclosure preferably satisfy the following conditions (1) to (4).

(1) Volume ratio (a) in 0.7 μm band of 5 vol % or more and 40 vol % or less

(2) Volume ratio (b) in 13 μm band of 20 vol % or more and 45 vol % or less

(3) Volume ratio (c) in 1.3 μm hand of 20 vol % or more and 50 vol % or less

(4) Sum of volume ratio (a), volume ratio (b), and volume ratio (c) from 60 vol % or more and 100 vol % or less

Here, the “0.7 μm band”, the “13 μm band”, and the “1.3 μm band” mentioned above are defined as follows.

0.7 μm band: particle size distribution having peak at 0.3 μm or more and less than 1.2 μm

13 μm band: particle size distribution having peak at 0.3 μm or more and less than 20 μm

1.3 μm band: particle size distribution having peak at 0.7 μm or more and less than 3 μm

The volume ratio (a), the volume ratio (b), and the volume ratio (c) of each band have peaks near 0.7 μm, 1.3 μm, and 13 μm in a particle size distribution curve, and are obtained by calculating an abundance ratio of particles in each band from a numerical integration of distribution curves obtained by further dividing the particle size distribution curve into three bands.

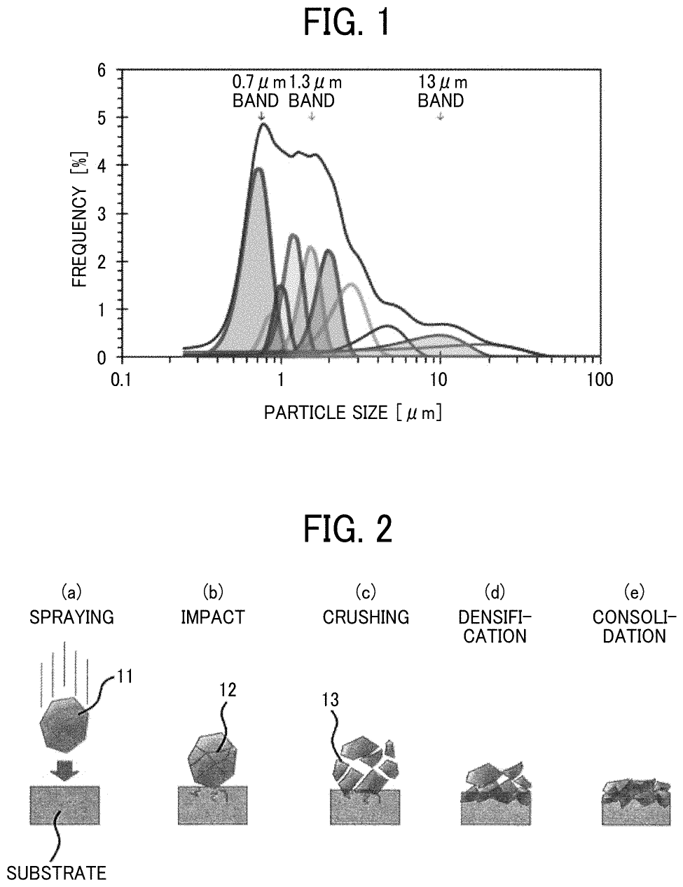

This relationship is represented in FIG. 1. The graph illustrated in FIG. 1 was obtained as follows.

Metal oxide particles were subjected to a particle size distribution measurement instrument, and a particle size distribution curve output from the particle size distribution measurement instrument was peak-divided by using numerical analysis software. The numerical analysis software may be ORIGINPRO from Lightstone Corp., PEAKFIT from Hulinks Inc., and FITYK. The abundance ratio of particles in each band was calculated by numerical integration of the peak-divided distribution curves. In general, tails of the peak-divided curves overlap. In the present disclosure, the distribution having the peak in each band was used to calculate the ratio by numerical integration.

The volume ratio (a) and the volume ratio (c) preferably satisfy Relational Expression (1) below.

Volume ratio (a)≤volume ratio (c) (1)

Particles having the volume ratio (a) in the 0.7 μm band have an effect of thickening a ceramic film, and particles having the volume ratio (c) in the 1.3 μm band have an effect on the adhesion of the ceramic film. If particles having the volume ratio (c) in the 1.3 μm band are added, ceramic particles can easily enter into the substrate. Therefore, a ceramic wedge is formed between the ceramic film produced on the surface and the substrate, and thus, it is possible to prevent the ceramic layer from peeling off Experiments indicate that sufficient adhesion can be obtained by choosing a value of the volume ratio (c) that is equal to or greater than the value of the volume ratio (a).

According to the metal oxide particles of the present disclosure, it is possible to easily form a tough metal oxide layer on a substrate containing a soft and fragile organic material that is different from an inorganic material such as glass, metal, and ceramics.

The metal oxide particles of the present disclosure can be applied to a ceramic coating by an AD method. Especially, in the AD method, the metal oxide particles of the present disclosure are advantageously used as a material for coating a substrate of an organic material with a tough metal oxide layer.

FIG. 2 is a simplified conceptual diagram of a phenomenon in which ceramic particles 11 form a film by the AD method. The mechanism of ceramic coating by the AD method may be explained with reference to FIG. 2 as follows. That is, in the ceramic particles 11 sprayed onto the substrate by the AD method, cracks 12 are formed due to collision and impact (see (a) and (b) of FIG. 2). Next, the particles are finely crushed, and an active new surface 13 is generated on a fracture surface of the crushed particles (see (c) of FIG. 2). Fine crystal fragments including the new surfaces 13 move and rotate on the substrate by the moment of inertia and the collision pressure, so that densification progresses (see (d) of FIG. 2) and the new surfaces 13 bond again and consolidate (see (e) of FIG. 2).

It can be understood that the ceramic film is formed by a sequential change of states in the order from (a) to (e) in FIG. 2. However, it is considered that the states from (a) to (e) in FIG. 2 actually exist simultaneously. Depending on the probabilities of these states, ceramic coatings are presumed to exhibit various phases.

In the spraying phase of (a) in FIG. 2, the focus is on erosion of the substrate surface. When the state in which the ceramic particles 11 collide with the substrate is not much different from sandblasting, erosion of the substrate surface progresses. The impact of sandblasting is different depending on the size of the medium, and thus, it is considered that a particle diameter of the ceramic particles 11 provided as a powder raw material determines the progress of erosion.

Such countermeasures against erosion are particularly desired when the substrate to be coated with the ceramic coating is a fragile organic material that is different from glass or metal, On the other hand, if the intention is to toughen the surface of the substrate by the ceramic coating, there is no meaning in applying the ceramic coating in a state where the powder raw material simply adheres to the surface of the substrate. Therefore, it is desirable to provide countermeasures that simultaneously achieve prevention of erosion of the substrate and the formation of a tough metal oxide surface in the ceramic coating by the AD method. The metal oxide particles of the present disclosure were obtained by repeated experiments with respect to these countermeasure. By satisfying the conditions (1) to (4) mentioned above, it is both possible to form a surface layer different from a layer in which a green compact is attached to the substrate surface, and to obtain an effect of excellent efficiency in the film formation of the ceramic coating.

In the present disclosure, the particle size distributions indicated in the conditions (1) to (4) mentioned above are measured under the following conditions.

Particle size distribution measurement device using laser diffraction or scattering method: MT3300EX II, manufactured by MicrotracBEL

Measurement method: dry

Compressed air used to disperse sample during measurement: 0.15 MPa

Temperature and humidity environment during measurement: 23±1° C., 50±3% RH

The metal oxide contained in the metal oxide particles of the present disclosure is not particularly limited, and examples thereof include, but are not limited to, CoO, NiO, FeO, Bi₂O₃, MoO₂, Cr₂O₃, SrCu₂O₂, CaO—Al₂O₃, Cu₂O, CuAlO, CuAlO₂, and CuGaO₂. Among these, an aspect in which the metal oxide contains elemental aluminum and/or elemental copper is preferable.

The metal oxide particles of the present disclosure contain the above-mentioned metal oxides as main components, and may suitably contain known additives for improving fluidization and anti-solidification properties, as desired.

(Laminated Body)

The laminated body of the present disclosure includes a metal oxide layer formed of the metal oxide particles of the present disclosure, and is a laminated body including, in this order, a substrate layer containing an organic material, a metal oxide mixed layer in which metal oxide particles are mixed, and a metal oxide layer formed of metal oxide particles.

<Substrate Layer>

A substrate layer is a layer containing an organic material.

When the metal oxide particles collide with the organic material of the substrate layer, the metal oxide is implanted into a surface portion of the substrate layer, and the surface portion of the substrate layer forms a metal oxide mixed layer in which the metal oxide and the organic material are mixed.

<Metal Oxide Mixed Layer>

The metal oxide mixed layer is a layer in which metal oxide particles are mixed. For example, the metal oxide mixed layer corresponds to a surface portion of the substrate where the metal oxide particles sprayed by coating in the AD method are implanted into the substrate surface. A wedge of metal oxide particles is formed to prevent the metal oxide layer formed on top of the surface portion of the substrate from peeling off

<Metal Oxide Layer>

The metal oxide layer is a layer formed of metal oxide particles. The metal oxide particles are bound together to form the layer, so that aggregation of the particles may or may not be observed.

Adhesion of the metal oxide layer is desirable for practical use of the device. With respect to this problem, it is effective to form a slightly uneven shape called anchoring over the entire surface of the substrate to be coated.

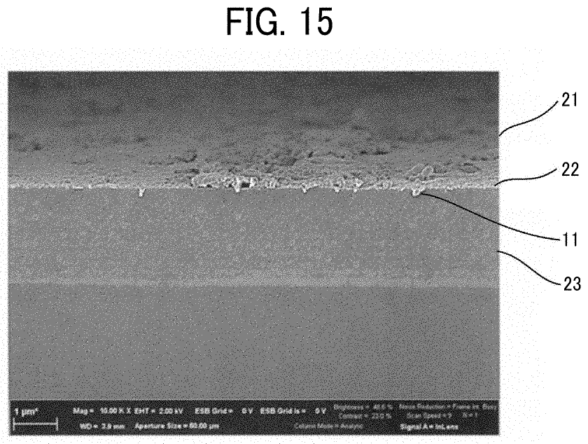

FIG. 15 is a diagram illustrating an embodiment of the laminated body of the present disclosure, and is a cross-sectional photograph captured by an electron microscope representing an example of a metal oxide mixed layer in the laminated body.

A metal oxide layer 21, a metal oxide mixed layer 22, and a substrate layer 23 containing an organic material are illustrated in this order from the top. In the metal oxide mixed layer, phases including the metal oxides are observed up to an interface with the substrate layer containing the organic material.

The metal oxide layer 21 and the metal oxide mixed layer 22 are described as examples in the embodiments of the present disclosure. That is, after forming a film of a material used as an undercoat layer, the metal oxide particles of the present disclosure are sprayed onto a surface of the undercoat layer by the AD method, whereby the laminated body illustrated in FIG. 15 can be manufactured.

Metal oxide particles 11 are implanted into the surface of the substrate layer 23 at a boundary between the substrate layer 23 and the metal oxide layer 21 to form the metal oxide mixed layer 22. The metal oxide particles 11 in the metal oxide mixed layer 22 act as wedges to prevent the metal oxide from peeling off.

The laminated body of the present disclosure may be applied to an electrophotographic photoconductor and a solar cell, for example.

The electrophotographic photoconductor and the solar cell are described below.

(Photoconductor)

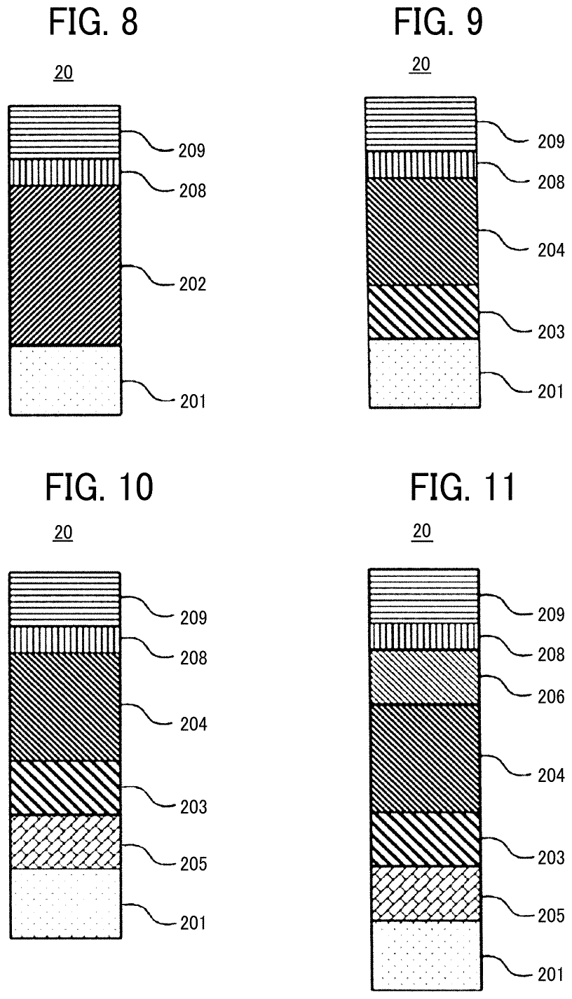

FIG. 8 is a schematic cross-sectional view for explaining a photoconductor that is an embodiment of the laminated body of the present disclosure.

In FIG. 8, a photoconductor 20 includes a photoconductive layer 202 provided on a conductive support body 201, and a metal oxide mixed layer 208 and a metal oxide layer 209 provided successively thereon. As described above, in the photoconductor 20, the metal oxide layer 209 is a ceramic film and the metal oxide mixed layer 208 contains a siloxane compound.

FIG. 9 is a schematic cross-sectional view for explaining another embodiment of the photoconductor of the present disclosure.

The photoconductor 20 in FIG. 9 is a photoconductor of a function-separated type in which the photoconductive layer 202 includes a charge generation layer (CGL) 203 and a charge transport layer (CTL) 204.

FIG. 10 is a schematic cross-sectional view for explaining another embodiment of the photoconductor of the present disclosure.

In the photoconductor 20 of FIG. 10, an undercoat layer 20.5 is provided between the support body 201 and the charge generation layer (CGL) 203 in the photoconductor of the function-separated type illustrated in FIG. 9.

FIG. 11 is a schematic cross-sectional view for explaining another embodiment of the photoconductor of the present disclosure.

In the photoconductor 20 in FIG. 11, a protective layer 206 is provided on the charge transport layer (CTL) 204 in the photoconductor of the function-separated type illustrated in FIG. 10.

FIG. 12 is a schematic cross-sectional view for explaining another embodiment of the photoconductor of the present disclosure.

In the photoconductor 20 in FIG. 12, an intermediate layer 207 is provided between the support body 201 and the undercoat layer 205 in the photoconductor of the function-separated type illustrated in FIG. 11.

The photoconductor of the present disclosure is not limited to the above-described embodiments. For example, as illustrated in FIG. 13, the photoconductor 20 may include the intermediate layer 207, the charge generation layer 203, the charge transport layer 204, the metal oxide mixed layer 208, and the metal oxide layer 209 in this order on the conductive support body 201.

In the photoconductor of the present disclosure, the organic photoconductor has excellent chargeability, the metal oxide layer is a ceramic film and thus has excellent abrasion resistance comparable to an inorganic photoconductor, and further, the metal oxide mixed layer contains a siloxane compound and thus has excellent gas barrier properties. Therefore, the photoconductor of the present disclosure has excellent durability and also has excellent image quality.

In particular, when the photoconductor includes a metal oxide mixed layer containing a siloxane compound, the photoconductive layer, which has high gas permeability and low strength, can be covered with a dense inorganic film, which improves the gas barrier properties. Furthermore, the metal oxide mixed layer in the present disclosure has a very high mechanical strength compared to organic materials, and can significantly improve the abrasion resistance of the photoconductor.

<Photoconductive Layer>

The photoconductive layer may be a multi-layer type photoconductive layer or a single-layer type photoconductive layer.

<<Multi-Layer Type Photoconductive Layer>>

As described above, the multi-layer type photoconductive layer includes at least a charge generation layer and a charge transport layer in this order and may also include other layers, as desired.

Charge Generation Layer

The charge generation layer contains at least a charge generating substance, and may also contain a binder resin and other components, as desired. The charge generating substance is not particularly limited and can be appropriately selected depending on the purpose, Both inorganic materials and organic materials may be used as the charge generating substance. Examples of the charge generating substance include, but are not limited to, crystalline selenium, amorphous selenium, selenium-tellurium, selenium-tellurium-halogen, selenium-arsenic compounds, phthalocyanine pigments such as metal phthalocyanines and metal-free phthalocyanines, and azo pigments having any one of a carbazole skeleton, a triphenylamine skeleton, a diphenylamine skeleton, and a fluorenone skeleton. Each of these may be used alone or in combination with others. The binder resin is not particularly limited and may be appropriately selected depending on the purpose, and examples thereof include, but are not limited to, a polyvinyl butyral resin and a polyvinyl formal resin. Each of these may be used alone or in combination with others.

Examples of a method of forming the charge generation layer include, but are not limited to, a vacuum thin film formation method and a casting method from a solution dispersion system.

Examples of an organic solvent used in a coating solution of the charge generation layer include, but are not limited to, methyl ethyl ketone and tetrahydrofuran. Each of these may be used alone or in combination with others. The thickness of the charge generation layer is generally preferably 0.01 μm or more and 5 μm or less, and more preferably 0.05 μm or more and 2 μm or less.

Charge Transport Layer

The purpose of the charge transport layer is to retain electrical charge and move charge generated and separated by exposure in the charge generation layer, to combine the generated charge with the retained electrical charge. To achieve the purpose of retaining the electrical charge, the charge transport layer preferably has high electrical resistance. To achieve the purpose of obtaining a high surface potential by the retained electrical charge, the charge transport layer preferably has a low dielectric constant and good charge mobility.

The charge transport layer contains at least a charge-transporting substance or a sensitizing dye, and may also contain a binder resin and other components, as desired.

Examples of the charge-transporting substance include, but are not limited to, hole-transporting substances, electron-transporting substances, and high molecular charge-transporting substances.

Examples of the electron-transporting substance (electron-accepting substance) include, but are not limited to, 2,4,7-trinitro-9-fluorenone and 1,3,7-trinitrodibenzothiophene-5,5-dioxide. Each of these may be used alone or in combination with others.

Examples of the hole-transporting substance (electron-donating substance) include, but are not limited to, triphenylamine derivatives and α-phenylstilbene derivatives. Each of these may be used alone or in combination with others. Examples of the high molecular charge-transporting substance include, but are not limited to, substances having the following structures. These examples include, but are not limited to, polysilylene polymers and polymers having a triarylamine structure.

For example, a polycarbonate resin or a polyester resin is used as the binder resin.

Each of these may be used alone or in combination with others.

The charge transport layer may further include a copolymer of a cross-linkable binder resin and a cross-linkable charge-transporting substance.

Examples of the sensitizing dyes include, but are not limited to, known metal complex compounds, coumarin compounds, polyene compounds, indoline compounds, and thiophene compounds.

The charge transport layer can be formed by dissolving or dispersing the charge-transporting substance or the sensitizing dye and the binder resin in a suitable solvent, applying the dissolved or dispersed solution, and drying the solution. In addition to the charge-transporting substance or the sensitizing dye and the binder resin, an appropriate amount of an additive such as a plasticizer, an antioxidant, and a leveling agent may further be added to the charge transport layer, as desired.

The thickness of the charge transport layer is preferably 5 μm or more and 100 μm or less. In recent years, there is a demand for high image quality, and thus, it is preferable that the charge transport layer is thin, and to achieve a high image quality of 1200 dpi or more, the thickness of the charge transport layer is more preferably 5 μm or more and 30 μm or less.

<<Single-Layer Type Photoconductive Layer>>

The single-layer type photoconductive layer contains a charge-generating substance, a charge-transporting substance, and a binder resin, and may further contain other components, as desired.

Similar materials as those of the multi-layer type photoconductive layer may be used as the charge-generating substance, the charge-transporting substance, and the binder resin.

If a single-layer type photoconductive layer is provided by a casting method, in many cases, such a single-layer type photoconductive layer is formed by dissolving or dispersing a charge-generating substance and a low molecular or high molecular charge-transporting substance in a suitable solvent, applying the dissolved or dispersed solution, and drying the solution. The single-layer type photoconductive layer may further contain a plasticizer and a binder resin, as desired. As the binder resin, a binder resin similar to the one of the charge transport layer may be used, or alternatively, the binder resin may be used in combination with a binder resin similar to the one of the charge generation layer.

The thickness of the single-layer type photoconductive layer is preferably 5 μm or more and 100 μm or less, and more preferably 5 μm or more and 50 μm or less. If the thickness is less than 5 μm, the chargeability may decrease, and if the thickness exceeds 100 μm, the sensitivity may decrease.

<Support Body>

The support body can be appropriately selected depending on the purpose, and for example, a conductive support body can be used as the support body. For example, a conductor or an insulator subjected to a conductive treatment is suitable as the support body. Examples of the support body include, but are not limited to metals such as Al and Ni, or alloys thereof; a support body obtained by forming a thin film of a metal such as Al or a conductive material such as In₂O₃ and SnO₂ on an insulating substrate such as polyester or polycarbonate; a resin substrate in which a metal powder such as carbon black, graphite, Al, Cu, and Ni, or a conductive glass powder are uniformly dispersed in a resin to impart conductivity to the resin, and a paper subjected to a conductive treatment.

The shape and the size of the support body are not particularly limited, and the support body may be plate-shaped, drum-shaped, or belt-shaped.

An undercoat layer may be provided between the support body and the photoconductive layer, as desired. The undercoat layer is provided for the purpose of improving adhesiveness, preventing moire, improving the coatability of an upper layer, and reducing the residual potential.

The undercoat layer generally contains a resin as a main component. Examples of these resins include, but are not limited to, alcohol-soluble resins such as polyvinyl alcohol, copolymerized nylon and methoxymethylated nylon, and curable resins that form a three-dimensional network structure, such as polyurethane, melamine resin, and alkyd-melamine resin.

Fine powders of metal oxides such as titanium oxide, silica, alumina, zirconium oxide, tin oxide, and indium oxide, or metal sulfides and metal nitrides may also be added to the undercoat layer. These undercoat layers can be formed by a commonly used coating method using a suitable solvent.

The thickness of the undercoat layer is not particularly limited and can be appropriately selected according to the purpose, and the thickness of the undercoat layer is preferably 0.1 μm or more and 10 μm or less, and more preferably 1 μm or more and 5 μm or less.

In the photoconductor, a protective layer may be provided on the photoconductive layer for the purpose of protecting the photoconductive layer. Materials used for the protective layer include, but are not limited to, resins such as ABS resins, ACS resins, an olefin-vinyl monomer copolymer, chlorinated polyether, aryl resins, phenolic resins, polyacetal, polyamide, polyamideimide, polyacrylate, polyallylsulfone, polybutylene, polybutylene terephthalate, polycarbonate, polyethersulfone, polyethylene, polyethylene terephthalate, polyimide, acrylic resins, polymethylpentene, polypropylene, polyphenylene oxide, polysulfone, polystyrene, polyarylate, AS resins, a butadiene-styrene copolymer, polyurethane, polyvinyl chloride, polyvinylidene chloride, and epoxy resins.

As a method of forming the protective layer, conventional methods such as an immersion coating method, spray coating, bead coating, nozzle coating, spinner coating, and ring coating may be used.

In the photoconductor, an intermediate layer may be provided on the support body to improve adhesion and charge-blocking properties, as desired. The intermediate layer generally includes a resin as a main component. Considering that the photoconductive layer is coated on the resin by using a solvent, it is desirable that the resin has high solvent resistance to general organic solvents.

Examples of the resin include, but are not limited to, water-soluble resins such as polyvinyl alcohol, casein, and sodium polyacrylate, alcohol-soluble resins such as copolymerized nylon and methoxymethylated nylon, and curable resins that form a three-dimensional network structure, such as polyurethane resin, melamine resin, phenolic resin, alkyd-melamine resin, and epoxy resin.

<Metal Oxide Mixed Layer>

The metal oxide mixed layer contains a siloxane compound. The siloxane compound is formed by cross-linking an organosilicon compound having one of a hydroxyl group or a by group.

The siloxane compound can fix the metal oxide layer on the surface of the photoconductor, improve the gas barrier properties, and strongly improve abrasion resistance.

Siloxane Compound

The siloxane compound is formed by cross-linking an organosilicon compound having one of a hydroxyl group or a hydrolyzable group. The siloxane compound may further contain a catalyst, a cross-linking agent, an organosilica sol, a silane coupling agent, and a polymer such as an acrylic polymer, as desired.

The cross-linking method is not particularly limited and can be appropriately selected according to the purpose, hut thermal cross-linking is preferable.

Examples of the organosilicon compound having one of a hydroxyl group or a hydrolyzable group include, but are not limited to, compounds having an alkoxysilyl group, partially hydrolyzed condensates of compounds having an alkoxysilyl group, and mixtures thereof.

Examples of the compounds having an alkoxysilyl group include, but are not limited to, tetraalkoxysilanes such as tetraethoxysilane, alkyltrialkoxysilanes such as methyltriethoxysilane, and aryltrialkoxysilanes such as phenyltriethoxysilane.

In addition, it is also possible to use compounds obtained by introducing an epoxy group, a methacryloyl group, or a vinyl group into the compounds mentioned above.

The partially hydrolyzed condensates of compounds having an alkoxysilyl group can be produced by known methods such as a method of adding a predetermined amount of water, a catalyst, and the like to the compound having an alkoxysilyl group to cause the compound to react.

Raw materials of the siloxane compound may be commercially available products. Specific examples thereof include, but are not limited to, GR-COAT (manufactured by Daicel Chemical Industries, Ltd.), GLASS RESIN (manufactured by Owens Corning Corporation), heatless glass (manufactured by Ohashi Chemical Industries, Ltd.), NSC (manufactured by Nippon Fine Chemical Co., Ltd.), glass stock solutions GO150SX and GO200CL (manufactured by Fine Glass Technologies Co., Ltd.), MKC SILICATE (manufactured by Mitsubishi Chemical Corporation) as a copolymer of an alkoxysilyl compound with an acrylic resin or a polyester resin, and silicate/acrylic varnish XP-1030-1 (manufactured by Dainippon Shikizai Kogyo Co., Ltd.). The raw material of the siloxane compound may also be referred to as a curable siloxane resin.

The thickness of the metal oxide mixed layer is preferably 0.01 μm or more and 4.0 μm or less, more preferably 0.03 μm or more and 4.0 μm or less, and still more preferably 0.05 μm or more and 2.5 μm or less. Further, the thickness of the metal oxide mixed layer is preferably 0.1 μm or more and 2.5 μm or less. Among these, the thickness of the metal oxide mixed layer is particularly preferably 0.01 μm or more and 2.5 μm or less.

The metal oxide contained in the metal oxide mixed layer is derived from an aerosol powder in the AD method.

<Metal Oxide Layer>

The metal oxide layer in the photoconductor includes a ceramic film.

Ceramics forming the ceramic film are generally metal oxides obtained by tiring metals. The ceramics are not particularly limited and can be appropriately selected depending on the purpose. Examples thereof include, but are not limited to, metal oxides such as titanium oxide, silica, alumina, zirconium oxide, tin oxide, and indium oxide. The ceramics preferably contain a transparent conductive oxide, and the transparent conductive oxide is preferably a ceramic semiconductor. The transparent conductive oxide preferably contains delafossite or perovskite, and the delafossite preferably contains copper aluminum oxide, copper chromium oxide, or copper gallium oxide. Perovskite is a composite material of an organic compound and an inorganic compound, and can be represented by the following general formula (1).

X_{α}Y_{β}M₆₅ General Formula (1)

In the general formula (1) above, the ratio of α:β:γ is 3:1:1, and β and γ represent integers greater than 1. For example, X may be a halogen ion, Y may be an ion of an alkylamine compound, and M may be a metal ion.

<Ceramic Semiconductor>

Among ceramics, the term “ceramic semiconductor” refers to ceramics that have partial defects in the normal electron configuration due to oxygen deficiency or the like, and is a general term for compounds that exhibit conductivity under specific conditions by the defects in the electron configuration. The metal oxide layer in the present disclosure is preferably a metal oxide-containing layer, and the metal oxide-containing layer is characterized by exhibiting conductivity under specific conditions by defects in the electron configuration, and the metal oxide layer is defined as a layer in which ceramic semiconductor components are densely arranged with no space therebetween and which does not contain an organic compound. The metal oxide-containing layer preferably contains delafossite. In the present disclosure, it is preferable to have charge mobility of any one of holes or electrons. The charge mobility of the metal oxide-containing layer is preferably 1×10⁻⁶ cm²/Vsec or more at an electric field intensity of 2×10⁻⁴ V/cm. In the present disclosure, it is preferable that the charge mobility is high. Here, a measurement method of the charge mobility is not particularly limited, and a general measurement method may be appropriately selected according to the purpose. Examples thereof include, but are not limited to, a method of preparing a sample and performing measurement according to the procedure described in Japanese Unexamined Patent Application Publication No. 2010-183072. Further, it is preferable that the bulk resistance including the thickness of the metal oxide-containing layer is less than 1×10^{13Ω.}

Delafossite

The delafossite (may be referred to as “p-type semiconductor” or “p-type metal compound semiconductor” hereinafter) is not particularly limited and can be appropriately selected according to the purpose, as long as the selected delafossite functions as a p-type semiconductor. Examples thereof include, but are not limited to, p-type metal oxide semiconductors, p-type compound semiconductors containing monovalent copper, and other p-type metal compound semiconductors. Examples of the p-type metal oxide semiconductors include, but are not limited to, CoO, NiO, FeO, Bi₂O₃, MoO₂, MoS₂, Cr₂O₃, SrCu₂O₂, and CaO—Al₂O₃. Examples of the p-type compound semiconductors containing monovalent copper include, but are not limited to, CuI, CuInSe₂, Cu₂O, CuSCN, CuS, CuInS₂, CuAlO, CuAlO₂, CuAlSe₂, CuGaO₂, CuGaS₂, and CuGaSe₂. Examples of the other p-type metal compound semiconductors include, but are not limited to, GaP, GaAs, Si, Ge, and SiC.

From the viewpoint of improving the effect of the present disclosure, the delafossite is preferably copper aluminum oxide, and the copper aluminum oxide is more preferably CuAlO₂.

(Solar Cell)

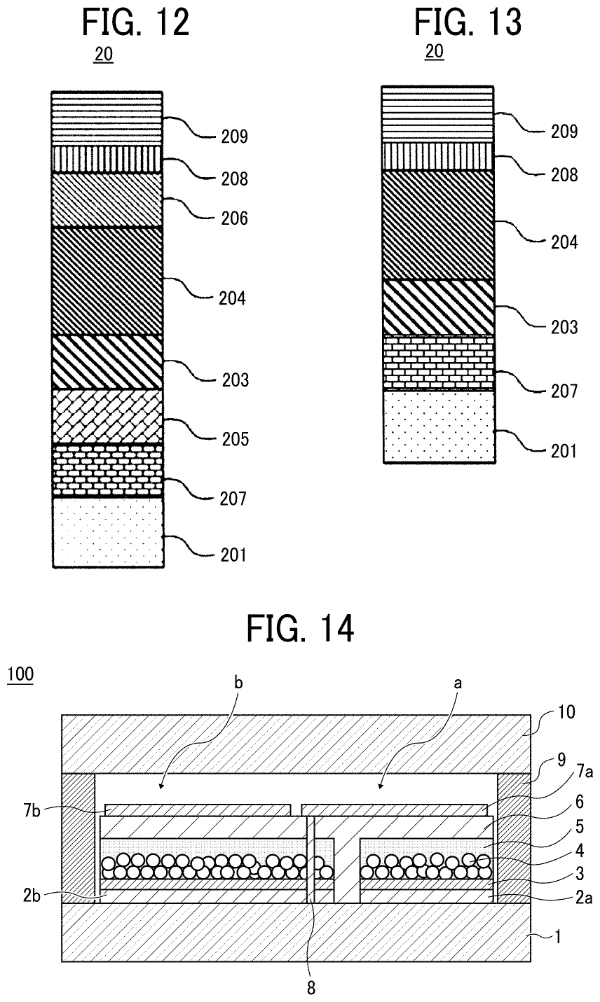

FIG. 14 is an explanatory diagram illustrating a perovskite solar cell as an example of the laminated body of the present disclosure.

As illustrated in FIG. 14, a perovskite solar cell module 100 includes, on a first substrate 1, photoelectric conversion elements a and h including first electrodes 2a and 2b, a dense electron transport layer (dense layer) 3, a porous electron transport layer (porous layer) 4, a perovskite layer 5, a hole transport layer 6, and second electrodes 7a and 7b.

One of the first electrodes 2a and 2b and one of the second electrodes 7a and 7b each include a penetrating portion 8 that conducts to an electrode extraction terminal.

In the perovskite solar cell module 100, a second substrate 10 is arranged to face the first substrate 1 to sandwich the photoelectric conversion element, and a sealing member 9 is arranged between the first substrate 1 and the second substrate 10.

In the perovskite solar cell module 100, the hole transport layer 6, which is an extended continuous layer, separates the first electrode 2a and the first electrode 2b.

Any of the electron transport layer, the perovskite layer, and the hole transport layer can be formed by using the metal oxide particles of the present disclosure.

In the laminated body of the present disclosure, a metal oxide layer including the metal oxide particles of the present disclosure is provided on a substrate layer containing an organic material. The metal oxide layer may be provided by using a known aerosol deposition method (AD method).

Examples of the layer containing an organic material include, but are not limited to, plastic substrates,

The thickness of the metal oxide layer is, for example, 0.05 μm or more and 10 μm or less, and is preferably 0.1 μm or more and less than 5 μm.

In a preferred embodiment of the laminated body of the present disclosure, the laminated body includes a layer containing an organic material, a layer containing a silicone compound contacting the layer containing the organic material, and a metal oxide layer contacting the layer containing the silicone compound.

The layer containing the silicone compound is not particularly limited and can be appropriately selected according to the purpose as long as the layer contains a polysiloxane structure. If the layer containing the silicone compound has a polysiloxane structure, an effect of preventing the metal oxide layer from peeling off is obtained.

The layer including a silicone compound may be formed by cross-linking an organosilicon compound having one of a hydroxyl group or a hydrolyzable group, and may further contain a catalyst, a cross-linking agent, an organosilica sol, a silane coupling agent, and a polymer such as an acrylic polymer, as desired.

The cross-linking method is not particularly limited and can be appropriately selected according to the purpose, but thermal cross-linking is preferable.

Examples of the organosilicon compound having one of a hydroxyl group or a hydrolyzable group include, but are not limited to, compounds having an alkoxysilyl group, partially hydrolyzed condensates of compounds having an alkoxysilyl group, and mixtures thereof.

Examples of the compounds having an alkoxysilyl group include, but are not limited to, tetraalkoxysilanes such as tetraethoxysilane, alkyltrialkoxysilanes such as methyltriethoxysilane, and aryltrialkoxysilanes such as phenyltriethoxysilane.

In addition, it is also possible to use compounds obtained by introducing an epoxy group, a methacryloyl group, or a vinyl group into the compounds mentioned above.

The partially hydrolyzed condensates of compounds having an alkoxysilyl group can be produced by known methods such as a method of adding a predetermined amount of water, a catalyst, and the like to the compound having an alkoxysilyl group to cause the compound. to react.

Raw materials of the layer including a silicone compound may be commercially available products. Specific examples thereof include, but are not limited to, GR-COAT (manufactured by Daicel Chemical industries, Ltd.), GLASS RESIN (manufactured by Owens Coming Corporation), heatless glass (manufactured by Ohashi Chemical Industries, Ltd.), NSC (manufactured by Nippon Fine Chemical Co., Ltd), glass stock solutions GO150SX and GO200CL (manufactured by Fine Glass Technologies Co., Ltd.), MKC SILICATE (manufactured by Mitsubishi Chemical Corporation) as a copolymer of an alkoxysilyl compound with an acrylic resin or a polyester resin, silicate/acrylic varnish XP-1030-1 (manufactured by Dainippon Shikizai Kogyo Co., Ltd.), and NSC-5506 (manufactured by Nippon Fine Chemical Co., Ltd,).

The layer containing a silicone compound may contain a monoalkoxysilane such as trimethylethoxysilane, trimethylmethoxysilane, tripropylethoxysilane, and trihexylethoxysilane as constituent components for the purpose of preventing cracks.

### EXAMPLES

The present disclosure will be further described below with reference to examples and comparative examples. However, the present disclosure is not limited to the following examples. In the following description, the term “parts” refers to “parts by mass” and the term “percent” refers to “mass %”, unless specified otherwise.

(Production of Metal Oxide Particles)

2 kg of copper(I) oxide (NC.-803, manufactured by Nippon Chemical Industrial Co., Ltd.) and 1.43 kg of alumina (AA-03, manufactured by Sumitomo Chemical Co., Ltd.) were mixed and heated at 1100° C. for 40 hours, to obtain copper aluminum oxide. The obtained copper aluminum oxide was pulverized by a dry disperser (DRY STAR SDA1, manufactured by Ashizawa Finetech Ltd.). [Metal oxide particles 1] to [metal oxide particles 5] of copper aluminum oxide exhibiting the following particle size distribution were obtained by changing the feed amount of the powder raw material and the rotation speed of a propeller of the dry disperser. The [metal oxide particles 1] to [metal oxide particles 5] were produced under the production conditions listed in Table 1.

Table 2 lists the particle size distribution of the [metal oxide particles 1] to [metal oxide particles 5].

The particle size of the [metal oxide particles 1] to [metal oxide particles 5] was measured by using a laser diffraction/scattering particle size distribution measurement device (MT-3300EX, manufactured by MicrotracBEL Corp.) in dry mode under conditions of a pressure of 0.2 MPa.

TABLE 1

| | | Media | | | | |
|---|---|---|---|---|---|---|
| | Media | filling | Peripheral | Feed | | Electric |
| Metal oxide | diameter | amount | speed | amount | Opening | power |
| particles No. | [mm] | [kg] | [m/s] | [kg/h] | [mm] | [kWh] |
| Metal oxide | 3.0 | 2.48 | 4 | 1 | 1.5 | 0.22 |
| particles 1 | | | | | | |
| Metal oxide | 3.0 | 2.48 | 4 | 3 | 1.5 | 0.08 |
| particles 2 | | | | | | |
| Metal oxide | 3.0 | 2.48 | 3 | 5 | 1.5 | 0.04 |
| particles 3 | | | | | | |
| metal oxide | 1.5 | 2.46 | 4 | 1 | 1.0 | 0.34 |
| particles 4 | | | | | | |
| Metal oxide | 1.5 | 2.46 | 5 | 1 | 1.0 | 0.82 |
| particles 5 | | | | | | |

Common conditions: addition of 1% dispersion assisting agent (ethanol), media type: PSZ balls, media filling rate: 70%

TABLE 2

| | Volume ratio | Volume ratio | Volume ratio | (a) + |
|---|---|---|---|---|
| Metal oxide | (a) in 0.7 μm | (b) in 13 μm | (c) in 1.3 μm | (b) + (c) |
| particles No. | band [%] | band [%] | band [%] | [%] |
| Metal oxide | 10 | 30 | 25 | 65 |
| particles 1 | | | | |
| Metal oxide | 5 | 20 | 50 | 75 |
| particles 2 | | | | |
| Metal oxide | 37 | 42 | 13 | 92 |
| particles 3 | | | | |
| Metal oxide | 50 | 30 | 10 | 90 |
| particles 4 | | | | |
| Metal oxide | 75 | 20 | 0 | 95 |
| particles 5 | | | | |

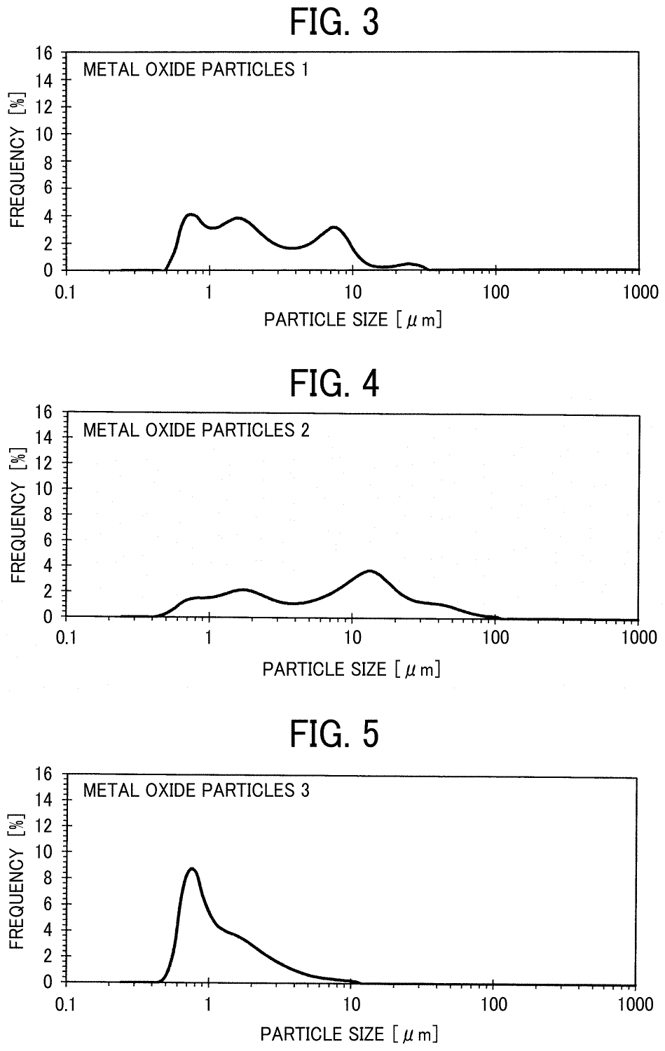

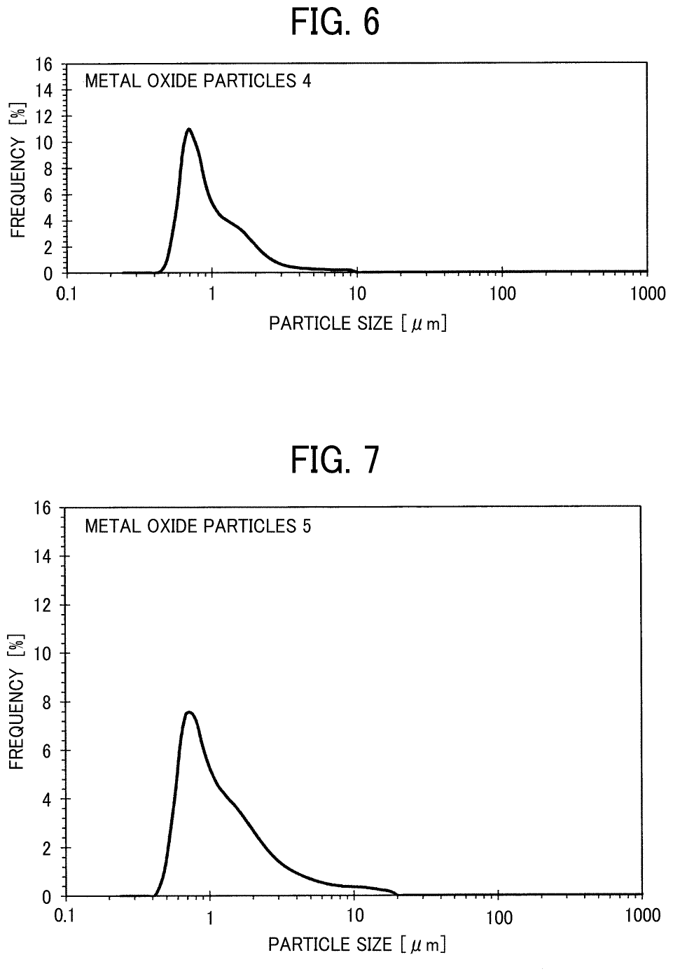

The particle size distributions of the [metal oxide particles 1] to the [metal oxide particles 5] are illustrated in FIGS. 3 to 7.

### Example 1

An intermediate layer coating liquid described below was applied onto an aluminum conductive support body (haying an outer diameter of 100 mm) by an immersion method to form an intermediate layer. The average thickness of the intermediate layer after drying at 165° C. for 30 minutes was 3 μm.

(Intermediate Layer Coating Liquid)

Zinc oxide particles (MZ-300, manufactured by TAYCA Co., Ltd.):
340 parts
3,5-Di-t-butylsalicylic acid (TCI-D1947, manufactured by Tokyo
Chemical Industry Co., Ltd.): 1.5 parts
Blocked isocyanate (SUMIDUR (registered trademark) 3175, having
a solid content concentration of 75%, manufactured by Suniika
Bayer Urethane Co., Ltd,): 60 parts
Solution obtained by dissolving 20% butyral resin in 2-butanone
(BM-1, manufactured by Sekisui Chemical Co., Ltd.): 230 parts
2-Butanone: 365 parts
Formation of Charge Generation Layer -

A charge generation layer coating liquid described below was applied onto the obtained intermediate layer by immersion coating to form a charge generation layer.

The average thickness of the charge generation layer was 0.3 μm.

(Charge Generation Layer Coating Liquid)

Y-Type titanyl phthalocyanine: 6 parts
Butyral resin (S-LEC BX-1, manufactured by Sekisui Chemical Co.,
Ltd.): 4 parts
2-Butanone (manufactured by Kanto Chemical Co., Inc.): 200 parts
Formation of Charge Transport Layer -

A charge transport layer coating liquid 1 described below was applied onto the 0 obtained charge generation layer by immersion coating to form a charge transport layer.

The average thickness of the charge transport layer after drying at 135° C. for 20 minutes was 23 μm.

(Charge Transport Layer Coating Liquid 1)

| | |
|---|---|
| Bisphenol-Z-type polycarbonate (PANLITE TS-2050, manufactured by | 10 parts |
| TEIJIN LIMITED): | |
| Low molecular charge-transporting substance having the structure below: | 10 parts |

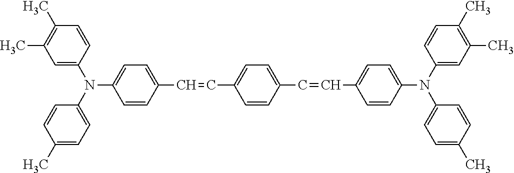

| | |
|---|---|
| Tetrahydrofuran: | 78 parts |
| Formation of Undercoat Layer - | |

An undercoat layer coating liquid described below was applied onto the obtained charge transport layer by a ring coating method to form an undercoat layer. The average thickness of the undercoat layer after drying at 120° C. for 20 minutes was 0.5 μm.

(Undercoat Layer Coating Liquid)

| | |
|---|---|
| Siloxane compound-containing coating (NSC-5506, manufactured by Nippon | 180 parts |
| Fine Chemical Co., Ltd.): | |
| Trimethylethoxysilane (manufactured by Tokyo Chemical Industry Co., Ltd.): | 6 parts |
| Polysilane (OGSOL SI-10-40, manufactured by Osaka Gas Chemicals Co., Ltd.): | 8 parts |
| Charge-transporting substance having the structure below (manufactured by | 7 parts |
| Ricoh Co., Ltd.): | |

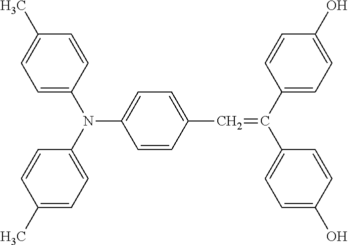 [SMILES: Cc1ccc(N(c2ccc(C)cc2)c2ccc(C=C(c3ccc(O)cc3)c3ccc(O)cc3)cc2)cc1]

| | |
|---|---|
| Ethylene glycol dimethyl ether (manufactured by FUJIFILM Wako Pure | 90 parts |
| Chemical, Corp.): | |
| Tetrahydroxyfuran (manufactured by Mitsubishi Chemical Corporation): | 90 parts |
| Formation of Metal Oxide Layer - | |

A metal oxide layer was formed on the obtained undercoat layer by the AD method using the [metal oxide particles 1].

The average thickness of the metal oxide layer was 0.6 μm.

The film of the metal oxide layer was formed by the AD method under the following conditions.

(Film Formation Conditions)

Raw material: [metal oxide particles 1]
Water content of copper aluminum oxide particles: 0.2% or less
(value measured bv Karl Fischer moisture meter)
Dew point temperature when filling metal oxide particles into
container: −53° C.
Aerosolization gas type: Nitrogen gas
Aerosolization gas flow rate: 5 L/min (total amount)
Vacuum degree in film formation chamber: 55 Pa
Angle between nozzle and photoconductor drum: 80 degrees
Distance between nozzle and photoconductor drum: 30 mm
Coating speed: 20 mm/min
Drum rotation speed: 20 rpm
Number of coating processes: 6 (3 round trips)

Thus, a metal oxide-organic substance hybrid device was obtained.

### (Example 2

A metal oxide-organic substance hybrid device was obtained by a method similar to Example 1, except that the [metal oxide particles 1] subjected to the AD method used in Example 1 were changed to [metal oxide particles 2]. The average thickness of the metal oxide layer was 0.3 μm.

### Comparative Example 1

A metal oxide-organic substance hybrid device was obtained by a method similar to Example 1. except that the [metal oxide particles 1] subjected to the AD method used in Example 1 were changed to [metal oxide particles 3]. The average thickness of the metal oxide layer was less than 0.01 μm.

### Comparative Example 2

A metal oxide-organic substance hybrid device was obtained by a method similar to Example 1, except that the [metal oxide particles 1] subjected to the AD method used in Example 1 were changed to [metal oxide particles 4]. The average thickness of the metal oxide layer was 5 μm.

### Comparative Example 3

A metal oxide-organic substance hybrid device was obtained by a method similar to Example 1, except that the [metal oxide particles 1] subjected to the AD method used in Example 1 were changed to [metal oxide particles 5]. The average thickness of the metal oxide layer was 8 μm.

The metal oxide-organic substance hybrid devices of Example 1, Example 2, and Comparative Examples 1 to 3 obtained as described above were subjected to a scratch test. After the scratch test, a scratch site was observed by a confocal microscope to evaluate the depth of a groove produced by the test.

The depth of the groove varies depending on a setting load of a stylus in the scratch test. A coefficient α obtained from an approximated straight line described below was used as an evaluation index in a change rate of the groove depth with respect to the load.

Groove depth [μm]=α[μm/mN]×load [mN]+intercept (formula 1)

(Scratch Test)

Testing device: Ultra-thin film scratch tester CSR-2000 (Rhesca)
Scratch speed: 10 μm/s
Spring constant: 100 g/mm
Stylus diameter: 5 μmR
Excitation level: 100 μm
Excitation frequency: 45 Hz
Setting load: 5, 7, 9, 11, 13, 15 (mN)
(Observation of Groove Depth)
Testing device: Confocal microscope OPTELICS H-1200 (Lasertec)
Lens magnification: 50 times
Light source: White

Table 3 illustrates the test results.

TABLE 3

| | Metal oxide | |
|---|---|---|
| | particles No. | α [μm/mN] |
| Example 1 | Metal oxide | 0.053 |
| | particles 1 | |
| Example 2 | Metal oxide | 0.028 |
| | particles 2 | |
| Comparative | Metal oxide | 0.412 |
| Example 1 | particles 3 | |
| Comparative | Metal oxide | Evaluation not possible because |
| Example 2 | particles 4 | metal oxide layer peeled off |
| | | from undercoat layer |
| Comparative | Metal oxide | Evaluation not possible because |
| Example 3 | particles 5 | metal oxide layer peeled off |
| | | from undercoat layer |

The metal oxide-organic substance hybrid devices of Example 1 and Example 2 are tougher than in Comparative Example 1. In the metal oxide-organic substance hybrid devices of Comparative Example 2 and Comparative Example 3, the metal oxide layer had the advantage of high film forming efficiency. However, the metal oxide layer peeled off shortly after the start of the test, and thus, the metal oxide-organic substance hybrid devices of Comparative Example 2 and Comparative Example 3 were not tough.

As already mentioned, in the phase of (a) (spraying) in FIG. 2, the focus is on erosion of the substrate surface. When the state in which the metal oxide particles collide with the substrate is not much different from sandblasting, erosion of the substrate surface progresses. The impact of sandblasting is different depending on the size of the medium, and thus, it is considered that a particle diameter of the metal oxide particles provided as a powder raw material determines the progress of erosion.

The reason why the [metal oxide particles 3], which form a granulated product of a ceramic powder material, had an unsatisfactory ceramic coating is considered to be that the [metal oxide particles 3] had a particle size distribution with a high erosion rate. The [metal oxide particles 3] had a large ratio of particles having a particle diameter of about 2 μm. A copper aluminum oxide having a particle diameter of about 2 μm can be said to have a particle size distribution that is disadvantageous for forming a film of a metal oxide layer having an erosion rate that is faster than a deposition rate.

On the other hand, the [metal oxide particles 4] and the [metal oxide particles 5] form thicker metal oxide layers than other grades. A large ratio of these metal oxide particles have a particle diameter of about 0.7 μm. Contrary to the [metal oxide particles 3], it can be said that the particle size distribution is such that the deposition rate is faster than the erosion rate.

In the phase (b) (impact) in FIG. 2 and the phase (c) (crushing) in FIG. 2, the focus is on a relationship in which the particle size distribution of the [metal oxide particles 4], which form a granulated product of the ceramic powder material, indicates a smaller average particle diameter than in the [metal oxide particles 5], and a large ratio of particle sizes of about 0.7 μm. If the deposition rate of the metal oxide layer is determined only by the ratio of these particles, a metal oxide layer formed by the [metal oxide particles 4] is thicker than a metal oxide layer formed by the [metal oxide particles 5]. However, these orders are reversed, and thus, it is desirable to determine another factor that affects the deposition rate.

The [metal oxide particles 4] and the [metal oxide particles 5], which form granulated products of the ceramic powder material, differ only in the rotation speed of a propeller inside a vessel of a dry disperser used for granulation. Thus, the amount of electric power used for granulating the [metal oxide particles 4] and the [metal oxide particles 5] was 0.34 kWh (metal oxide particles 4) and 0.82 kWh (metal oxide particles 5), respectively. The [metal oxide particles 5] included many fume-like particles when the metal oxide particles were collected immediately after the dispersion treatment, and the metal oxide particles felt brittle when being touched, and thus, the particles of the [metal oxide particles 5] are considered to be fragile. For example, it is considered that there are more latent scratches incised in the particles of the [metal oxide particles 5] than the [metal oxide particles 4].

The phases (d) (densification) in FIG. 2 and (e) (consolidation) in FIG. 2 may be considered as phases in which the metal oxide layer is generated, and at the same time, phases that determine the adhesiveness between the metal oxide layer and the substrate layer.

If the [metal oxide particles 4] and the [metal oxide particles 5] are used, the metal oxide layer peels off easily. On the other hand, the metal oxide layers of the [metal oxide particles 1] and the [metal oxide particles 2] do not easily peel off. In particular, it was observed that anchoring, in which the metal oxide layer was penetrating into the substrate, proceeded in the [metal oxide particles 2]. These differences can be distinguished as the difference in the ratio of particle diameters of about 13 μm from the characteristics of the particle size distributions of the powder raw material. The particle diameter is nearly 100 times larger than the size of a particle shape ((φ 150 nm) observed in a cross-sectional SEM image of the metal oxide layer.

It is considered that small metal oxide particles adhering to the substrate are hit by large particles, and thus, anchoring, densification, and consolidation of the small particles proceeds. It is also conceivable that the internal stress amassed in the metal oxide layer is relaxed by mixing large particles into the metal oxide powder raw material.

The present disclosure relates to the metal oxide particles in (1) described below, and includes (2) to (10) described below as embodiments.

(1) Metal oxide particles satisfying conditions (1) to (4) described below:

(1) a volume ratio (a) in a 0.7 μm band of 5 vol % or more and 40 vol % or less,

(2) a volume ratio (b) in a 13 μm band of 20 vol % or more and 45 vol % or less,

(3) a volume ratio (c) in a 1.3 μm band of 20 vol % or more and 50 vol % or less, and

(4) a sum of the volume ratio (a), the volume ratio (b), and the volume ratio (c) of from 60 vol % or more and 100 vol % or less,

where:

the 0.7 μm band is defines as a particle size distribution having a peak at 0.3 μm or more and less than 1.2 μm,

the 13 μm band is defined as a particle size distribution having peak at 0.3 μm or more and less than 20 μm, and

the 1.3 μm band is defined as a particle size distribution having peak at 0.7 μm or more and less than 3 μm,

the volume ratio (a), the volume ratio (b), and the volume ratio (c) of each band having peaks near 0,7 μm, 1.3 μm, and 13 μm in a particle size distribution curve, and are obtained by calculating an abundance ratio of particles in each band from a numerical integration of distribution curves obtained by further dividing the particle size distribution curve into three bands.

(2) The metal oxide particles according to (1) described above, in which the volume ratio (a) and the volume ratio (c) satisfy Relational Expression (1) below.

Volume ratio (a)≤volume ratio (c) (1)

(3) The metal oxide particles according to (1) or (2) described above, in which the metal oxide particles contain delafossite and/or perovskite.

(4) A laminated body including a substrate layer containing an organic material and a metal oxide layer on the substrate layer containing the organic material, in which the metal oxide layer contains the metal oxide particles according to any one of (1) to (3) described above.

(5) The laminated body according to (4) described above, further including, between the substrate layer and the metal oxide layer, a metal oxide mixed layer in which the metal oxide particles of the metal oxide layer are mixed with the organic material of the substrate layer.

(6) The laminated body according to (4) or (5) described above, in which the substrate layer containing the organic material is a charge transport layer containing a charge-transporting substance or a dye electrode layer containing a sensitizing dye.

(7) A solar cell including: a support body; a first electrode layer over the support body; a hole blocking layer over the first electrode layer; a dye electrode layer over the hole blocking layer, which contains a sensitizing dye; a ceramic semiconductor layer over the dye electrode layer; and a second electrode layer over the ceramic semiconductor layer, in which the dye electrode layer, the ceramic semiconductor layer, and a boundary layer between the dye electrode layer and the ceramic semiconductor layer are the substrate layer, the metal oxide layer, and the metal oxide mixed layer of the laminated body according to (5) described above, respectively.

(8) A photoconductor including: a support body; an intermediate layer over the support body; a charge generation layer over the intermediate layer; a charge transport layer over the charge generation layer; and a ceramic layer over the charge transport layer, in which the charge transport layer, the ceramic layer, and a boundary layer between the charge transport layer and the ceramic layer are the substrate layer, the metal oxide layer, and the metal oxide mixed layer of the laminated body according to (5) described above, respectively.

(9) A method of manufacturing the metal oxide particles according to any one of (1) to (3) described above, including pulverizing a metal oxide powder raw material using a dry disperser including a propeller by adjusting a feed amount of the metal oxide powder raw material to the dry disperser, a rotation speed of the propeller of the dry disperser, a media diameter, and a media filling amount.

(10) A method of manufacturing a laminated body, including spraying the metal oxide particles according to any one of (1) to (3) described above onto a substrate layer containing an organic material, by an aerosol deposition method, to form a metal oxide mixed layer on the substrate layer and form a metal oxide layer on the metal oxide mixed layer, in which the metal oxide layer contains the metal oxide particles, and, in the metal oxide mixed layer, the metal oxide particles of the metal oxide layer are mixed with the organic material of the substrate layer.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention. Any one of the above-described operations may be performed in various other ways, for example, in an order different from the one described above.

1. Metal oxide particles satisfying conditions (1) to (4) below;
(1) a volume ratio (a) in a 0.7 μm band of 5 vol % or more and 40 vol % or less,
(2) a volume ratio (h) in a 13 μm band of 20 vol % or more and 45 vol % or less,
(3) a volume ratio (c) in a 1.3 μm band of 20 vol % or more and 50 vol % or less, and
(4) a sum of the volume ratio (a), the volume ratio (b), and the volume ratio (c) of 60 vol % or more and 100 vol % or less,
where:
the 0.7 μm band is defined as a particle size distribution having a peak at 0.3 μm or more and less than 1.2 μm,
the 13 μm band is defined as a particle size distribution having a peak at 0.3 μm or more and less than 20 μm, and
the 1.3 μm band is defined as a particle size distribution having a peak at 0.7 μm or more and less than 3 μm,
the volume ratio (a), the volume ratio (b), and the volume ratio (c) of each band having peaks near 0.7 μm, 1.3 μm, and 13 μm in a particle size distribution curve, and being obtained by calculating an abundance ratio of particles in each band from a numerical integration of distribution curves obtained by further dividing the particle size distribution curve into three bands.

2. The metal oxide particles according to claim 1, wherein the volume ratio (a) and the volume ratio (c) satisfy Relational Expression (1) below.
Volume ratio (a)≤volume ratio (c) (1)

3. The metal oxide particles according to claim 1, wherein the metal oxide particles comprise one or both of delafossite and perovskite.

4. A laminated body comprising:
a substrate layer containing an organic material; and
a metal oxide layer on the substrate layer, the metal oxide layer containing the metal oxide particles according to claim 1.

5. The laminated body according to claim 4, further comprising, between the substrate layer and the metal oxide layer, a metal oxide mixed layer in which the metal oxide particles of the metal oxide layer are mixed with the organic material of the substrate layer.

6. The laminated body according to claim 4, wherein the substrate layer containing the organic material is a charge transport layer containing a charge-transporting substance or a dye electrode layer containing a sensitizing dye.

7. A solar cell comprising:
a support body;
a first electrode layer over the support body;
a hole blocking layer over the first electrode layer;
a dye electrode layer over the hole blocking layer, the dye electrode layer containing a sensitizing dye;
a ceramic semiconductor layer over the dye electrode layer; and
a second electrode layer over the ceramic semiconductor layer,
wherein the dye electrode layer, the ceramic semiconductor layer, and a boundary layer between the dye electrode layer and the ceramic semiconductor layer are the substrate layer, the metal oxide layer, and the metal oxide mixed layer of the laminated body according to claim 5, respectively.

8. A photoconductor comprising:
a support body;
an intermediate layer over the support body;
a charge generation layer over the intermediate layer;
a charge transport layer over the charge generation layer; and
a ceramic layer over the charge transport layer,
wherein the charge transport layer, the ceramic layer, and a boundary layer between the charge transport layer and the ceramic layer are the substrate layer, the metal oxide layer, and the metal oxide mixed layer of the laminated body according to claim 5, respectively.

9. A method of manufacturing the metal oxide particles according to claim 1, the method comprising:
pulverizing a metal oxide powder raw material using a dry disperser including a propeller by adjusting a feed amount of the metal oxide powder raw material to the dry disperser, a rotation speed of the propeller of the dry disperser, a media diameter, and a media filling amount.

10. A method of manufacturing a laminated body, the method comprising:
spraying the metal oxide particles according to claim 1 onto a substrate layer containing an organic material, by an aerosol deposition method, to form a metal oxide mixed layer on the substrate layer and form a metal oxide layer on the metal oxide mixed layer,
wherein the metal oxide layer contains the metal oxide particles, and,
wherein, in the metal oxide mixed layer, the metal oxide particles of the metal oxide layer are mixed with the organic material of the substrate layer.
